(19) United States
(12) Patent Application Publication
(10) Pub. No.: US 2023/0193725 A1
(43) Pub. Date: Jun. 22, 2023

(54) SCORING A FINAL RISK FOR IDENTIFIED BOREHOLE DESIGN CONCEPTS

(71) Applicant: Landmark Graphics Corporation, Houston, TX (US)

(72) Inventors: Margareth Gibbons Parra, London (GB); Adolfo Gonzales, Houston, TX (US); Nitish Damodar Chaudhari, Houston, TX (US); Gabriel Tirado, Houston, TX (US)

(21) Appl. No.: 17/553,219

(22) Filed: Dec. 16, 2021

(51) Int. Cl. E21B 41/00; G06F 30/27; E21B 47/12

(52) U.S. Cl. CPC E21B 41/00; G06F 30/27; E21B 47/12; E21B 2200/22

(57) ABSTRACT

The disclosure presents processes for evaluating a borehole design against one or more identified risks. The processes can determine borehole design concepts for the borehole design. Each borehole design concept can have multiple risks assigned, which can be selected from a library of risks, a risk matrix or template, a risk model, or user entered risks. The risks can be scored using one or more statistics-based algorithms, such as a sum, an average, a mean, or other algorithms. The risks can be grouped by a risk level, forming a sub-risk score for each risk level for each borehole design concept. A final risk score can be generated using the sub-risk scores for the borehole design. More than one borehole design can be evaluated using a risk tolerance parameter and the borehole design that satisfies the risk tolerance parameter can be selected as the recommended borehole design.

### TECHNICAL FIELD

This application is directed, in general, to determining risk for a borehole design and, more specifically, to calculating risk score.

### BACKGROUND

When developing a borehole, or determining a location of a borehole, a borehole design needs to be developed. The borehole design can consist of one or more borehole design concepts, where the concepts are categories or groups of similar borehole factors, for example, casing, drill bit, subterranean formations, and other borehole factors. Each borehole design concept can have one or more risks associated with it. Conventionally, these risks are reviewed and evaluated by a user independent of other users and changing factors. It would be beneficial to be able to consistently manage the evaluation of risks for borehole designs.

### SUMMARY

In one aspects, a method to determine one or more risk scores for a borehole design of a borehole is disclosed. In one embodiment, the method includes (1) receiving borehole location parameters for the borehole, borehole associated data relating to the borehole, and a geographic location of interest for the borehole, (2) determining one or more borehole design concepts for the borehole utilizing the borehole location parameters, the borehole associated data, and the geographic location of interest, wherein the one or more borehole design concepts are utilized for the borehole design, (3) assigning one or more risks to each of the one or more borehole design concepts, (4) generating a sub-risk score for each of the one or more borehole design concepts using the one or more risks, and (5) generating a final risk score for the borehole design, using the sub-risk score for each of the one or more borehole design concepts.

In a second aspect, a system to determine one or more risk scores for a borehole design of a borehole is disclosed. In one embodiment, the system includes (1) a data transceiver, capable of receiving borehole location parameters for the borehole, borehole associated data relating to the borehole, and a geographic location of interest for the borehole, and (2) a borehole risk analyzer, capable of communicating with the data transceiver, determining one or more borehole design concepts for the borehole utilizing the borehole location parameters, the borehole associated data, and the geographic location of interest, wherein the one or more borehole design concepts are utilized for the borehole design, assigning one or more risks to each of the one or more borehole design concepts, generating a sub-risk score for each of the one or more borehole design concepts, and generating a final risk score for the borehole design, using the sub-risk score for each of the one or more borehole design concepts.

In a third aspect, a computer program product having a series of operating instructions stored on a non-transitory computer-readable medium that directs a data processing apparatus when executed thereby to perform operations to generate one or more risk scores for a borehole design of a borehole is disclosed. In one embodiment, the operations include (1) receiving borehole location parameters for the borehole, borehole associated data relating to the borehole, and a geographic location of interest for the borehole, (2) determining one or more borehole design concepts for the borehole utilizing the borehole location parameters, the borehole associated data, and the geographic location of interest, wherein the one or more borehole design concepts are utilized for the borehole design, (3) assigning one or more risks to each of the one or more borehole design concepts, (4) generating a sub-risk score for each of the one or more borehole design concepts using the one or more risks, and (5) generating a final risk score for the borehole design, using the sub-risk score for each of the one or more borehole design concepts.

### BRIEF DESCRIPTION

Reference is now made to the following descriptions taken in conjunction with the accompanying drawings, in which:

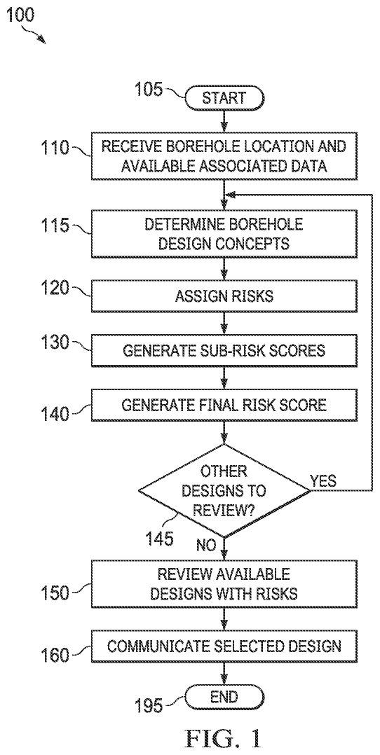

FIG. 1 is an illustration of a flow diagram of an example method to analyze borehole design concepts;

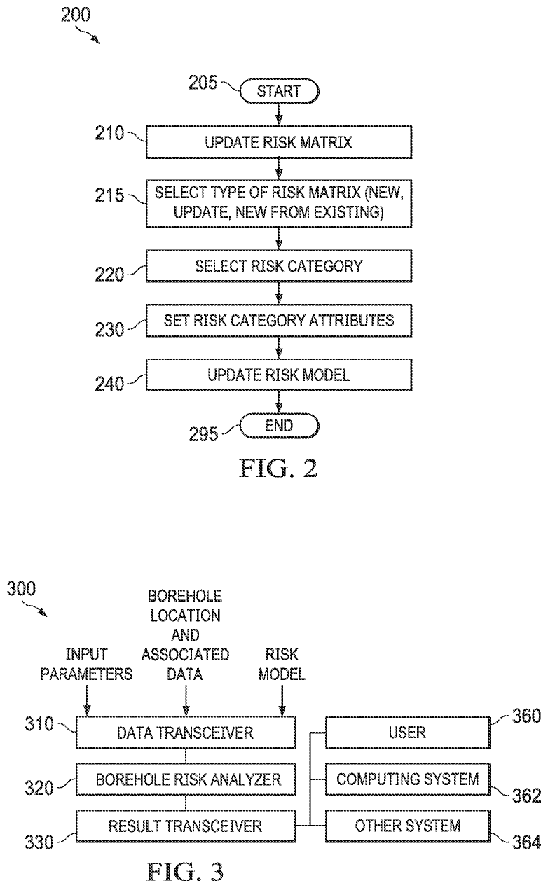

FIG. 2 is an illustration of a flow diagram of an example method to update a risk model;

FIG. 3 is an illustration of a block diagram of an example borehole design analyzer system;

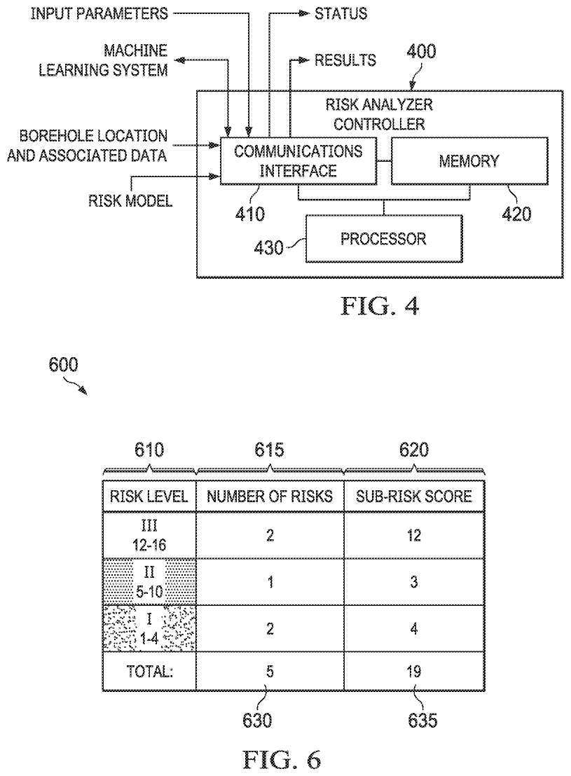

FIG. 4 is an illustration of a block diagram of an example of borehole design analyzer controller according to the principles of the disclosure;

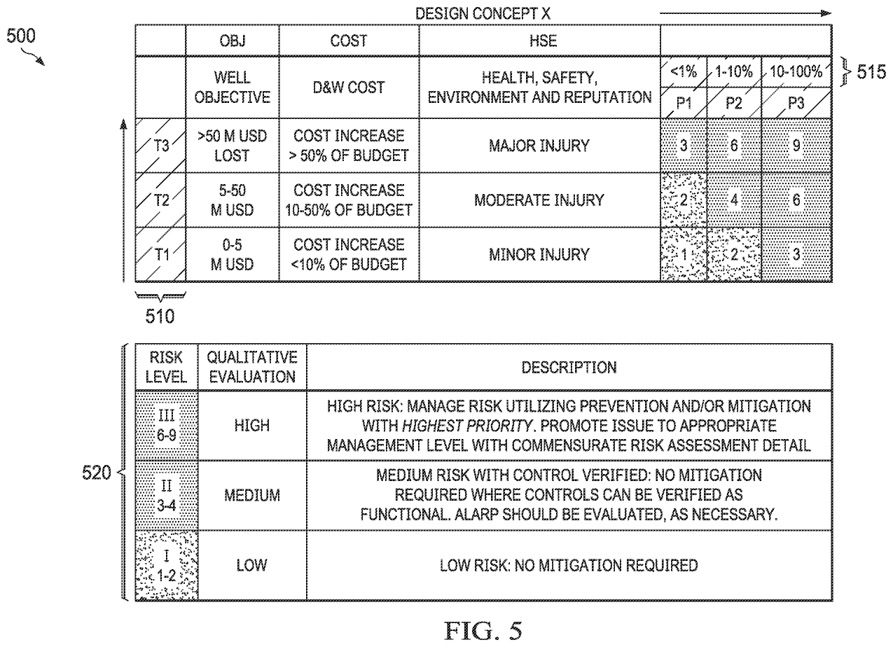

FIG. 5 is an illustration of a diagram of an example risk matrix; and

FIG. 6 is an illustration of a diagram of an example sub-risk score.

### DETAILED DESCRIPTION

In designing boreholes, such as for hydrocarbon production, scientific purposes, or other uses, the users need to account for many types of borehole factors. For this disclosure, the borehole includes both cased and uncased portions of the borehole. Borehole factors can include, but are not limited to, the location of the borehole (such as in a mountainous region, off shore, or other location types), the geology of the subterranean formations at one or more depths, the purpose of the borehole (hydrocarbon production, intercept, relief, scientific, or other purposes), equipment used for developing the borehole, the type of casing to be used, a time frame or time within which the borehole is to be developed, and other factors.

Understanding how each borehole factor contributes to an overall risk of developing the borehole can be difficult to state with confidence. Making changes to the borehole design, e.g., adjusting one or more borehole factors, can change the risk of one or more borehole factors thereby changing the overall risk of developing the borehole. An increase in risk can directly contribute to a potential increase in cost of developing the borehole as the risks result in impact on the operations. A user can have differing risk tolerances from other users, or differing risk tolerances for boreholes in different locations.

The current methods for evaluating the total risk identified for a borehole design are cumbersome and can lead to incorrect risk assessments for the borehole design. When designing a borehole, decisions made along the planning process of the borehole can generate design risks, which are normally controlled or mitigated by adjusting the design criteria or parameters (for example, changing the trajectory of the borehole, changing casing points, changing the type of casing, changing the fluid selection, or other changes). In some aspects, the borehole design can remain the same while the borehole operation plan can be updated to include mitigation actions for the anticipated risks. There can be inherited risks by deciding to drill the borehole in a specific location, for example, choosing to target a formation above a salt dome. Another example can be a subsea borehole location that may have a residual risk of locating a wellhead at sea level, since a minor earthquake at the mudline can make the wellhead change its altitude. These inherited risks are known as generic risks, and can be overcome by implementing precautions to mitigate their impact or probability of occurrence.

Conventionally, solutions may offer a risk assessment tool that produces results and analysis for customers in different scenarios. None of the presently available solutions provide application programming interfaces (APIs) that can be used in the hydrocarbon production industry that can connect to the borehole design process. Some solutions may provide an option to configure their tool to fit a customer project workflow, without providing an option to control the risk register tool configuration, the results, or the content. Solutions typically do not allow the user to configure the risk register to their own specifications, thus limiting the usage of risk registers across organizations.

This disclosure presents processes to allow users to record planning risks, generic risks, and residual risks, with an output to generate a final risk score for a design, enabling comparisons with alternate designs, having an ability to configure the risk calculations to align with standards and risk assumptions of the user. The processes can reduce the time to generate the final risk score thereby improving on-time decision making processes. A final risk score can also specify a sub-risk score per risk type, e.g., a concept, category, or group, for a borehole design. The final risk score and the zero or more sub-risk scores can be communicated to other systems, for example, to a library of borehole risks, a risk model, or a borehole operation system. As part of the borehole design process, a risk management tool can be utilized allowing the user to capture one or more risks at various steps of the borehole design process. The risk management tool can perform the processes and operations disclosed herein. The risk management tool can be configured to manage various risk management processes utilizing a risk matrix.

Typically the borehole design process involves multiple design concepts which are then compared and ranked according to various metrics, where risk is one of the measures. When the user has captured at least some of the risks, the processes can provide a risk evaluation, such as an initial risk or remaining risk, per design topic, e.g., each type of risk. A sub-risk score can be generated for each borehole design factor, e.g., concept, category, or group, and the sub-risks scores can be used to generate a final risk score for the overall borehole design. In some aspects, the user can specify the algorithm used to generate the sub-risk scores and the final risk score, for example, using a sum, average, mean, weighted value, or other statistics-based algorithm.

In some aspects, the processes can group the risks utilizing a risk level, for example, low-medium-high, or a number scale. The risks that fall within each risk level can be statistically aggregated to generate a risk level score. The statistical aggregation, e.g., specified algorithm, can be a sum, an average, a mean, a weighting value, or other statistics-based algorithms. The risk level scores can be utilized to generate the sub-risk scores for each design concept, utilizing a statistics-based algorithm. When comparing risks, the user can see the number of risks the design concept has and the sub-risk score that the design concept causes to be generated. The user can assess details of the risk evaluation, thereby improving the decision making for ranking and selecting one or more design concepts of the borehole design.

As part of the borehole design process, having a summary of identified risks during the planning phase, can assist in the decisions made in the detailed engineering process by focusing on the risks identified. Having standardized risks, such as from a risk matrix or a risk model, can increase confidence in the sub-risk scores and final risk scores that are generated.

Currently, users manage their risks differently which makes it difficult to consistently associate risks to the borehole design process. By having a risk management tool with sub-risk scores and a final risk score, it improves the speed and confidence level of the borehole design process. In some aspects, conditions measured or collected downhole a borehole can be used to update a borehole design and the risk assessment process, such as scoring the sub-risk scores and the final score can be updated with the data received from one or more sensors located downhole the borehole. The revised risk assessment can be used to update the existing borehole design and thereby update the borehole operation planning system.

In some aspects, the processes can communicate the results of the risk analysis from one phase to another, for example, from feasibility studies to detailed planning or from the planning phase to the execution phase, and back to planning for new boreholes. This flexibility can enable the user to include risk evaluations in their decision process. In some aspects, the processes provide for user input to customize the risk factors, such as for different users, project types, or locations (e.g., state, region, or country).

In some aspects, a risk matrix can be employed to allow users to build a risk model, e.g., to build on lessons learned. Knowledge gained through previous borehole design and development projects can be utilized as lessons learned to further build the risk model which can then update the risk matrix. The identification of inherent risks or generic risks from the risk matrix can be utilized to reduce the time to perform the risk analysis, and can potentially reduce the cost to users, where higher costs could be incurred through the assumption of risks, e.g., an approximation or estimation of risk. In some aspects, the processes can have an input on the risk tolerance of the user. The risk tolerance parameter can be utilized to flag or otherwise identify borehole designs that may be exceeding the risk tolerance.

Turning now to the figures, FIG. 1 is an illustration of a flow diagram of an example method 100 to analyze borehole design concepts. Method 100 can be performed on a computing system, for example, borehole design analyzer system 300 of FIG. 3 or borehole design analyzer controller 400 of FIG. 4. The computing system can be a reservoir controller, a data center, a cloud environment, a server, a laptop, a mobile device, or other computing system capable of receiving the seismic data, input parameters, and capable of communicating with other computing systems. Method 100 can be encapsulated in software code or in hardware, for example, an application, code library, dynamic link library, module, function, RAM, ROM, and other software and hardware implementations. The software can be stored in a file, database, or other computing system storage mechanism. Method 100 can be partially implemented in software and partially in hardware. Method 100 can perform the steps for the described processes, for example, evaluating one or more borehole designs and design concepts.

The ability to manage risks improves when a risk is identified earlier in the borehole design process. The processes allow users to register risks as the user is evaluating the borehole design and then add the identified risks to a collection of risks for the concept of the borehole design, where a concept is a category of borehole factors. For example, a concept can include factors for the drilling bit that will be used, for the type of casing that will be used, the type of borehole (production, intercept, relief, and other borehole types), directional drilling operations to be used, types of fluids, muds, or brines to be used, how many drilling feet per day is planned, mechanical or hydraulic failure planning, geology of the subterranean formations, surface characteristics, state or country location (geographic location of interest), and other category types. These processes allow team members to review the risks before determining a borehole design to move forward in a borehole operation plan.

As the user is adding risks, the setup of the risk assessment will require the user to perform a risk evaluation based on each company's safety criteria. By default, the process can allow the user to specify one or more parameters, for example, risk details, risk code, event, cause, consequence, borehole construction phase, initial risk assessment, impact value, probability value, risk value, mitigation actions, action, status, responsible, due date, residual risk assessment, and other input parameters.

In some aspects, the processes can collect all of the risks registered at the risk identification step in a risk assessment table. In some aspects, the risk assessment table can show the risk corresponding to a step or operation of the borehole operation plan. In some aspects, the risks can be assigned a unique number in the main risk library, e.g., a risk model, and a risk number per borehole design. The user can utilize these identifier numbers to identify the total number of risks identified in each design, and allow future analysis and filtering capabilities for historical risk evaluation.

In some aspects, as the risks are being added to the borehole design, a sub-risk score and a final risk score can be updated for the design. In these aspects, the risk scoring feedback can enable a faster evaluation of selected design concepts. In some aspects, the user can specify a risk scale or a risk tolerance level parameter. In some aspects, once the sub-risk scores for all design concepts are identified, the processes can aggregate the risks utilizing their risk level, showing a total number of risks identified per risk level and using a statistics-based algorithm to determine the risk score for each risk level, first by risk level and then by borehole design concept.

Method 100 starts at a step 105 and proceeds to a step 110. In step 110, borehole location parameters, along with available associated data can be received, e.g., borehole associated data. The borehole location parameters can include, for example, state, country, or region information, e.g., geographic location of interest. The associated data can include, for example, available drilling equipment near the borehole location, geological parameters, seismic data, cartographic reference systems, stratigraphic parameters, and other types of associated data.

In a step 115, borehole design concepts can be determined. The borehole design concepts can align with design factors for developing boreholes. For example, a type of drilling tool can be determined, a type of casing can be determined, a type of drilling mud can be determined, or other factors can be determined. Each of the borehole design concepts can group design factors by a determined category indicator for that borehole design concept.

In a step 120, risks can be assigned to each borehole design concept. In some aspects, risks can be assigned by the user entering in the risk parameters. The processes can calculate the risk and a residual risk using an algorithm, such as impact multiplied by probability (r=impact×probability).

In some aspects, risks can be assigned from a library of risks, such as stored as part of a risk model. The library of risks can be stored in various systems, such as a file, a database, a data store, or other system storages, and can be stored locally, in a cloud environment, a data center, a server, file system, laptop, mobile computing device, laptop, smartphone, or other locations.

In some aspects, risks can be copied from previously created borehole designs, e.g., using a risk template. This can provide an initial listing of risks that can be tailored by a user. In some aspects, the user can select a risk matrix, e.g., a type of risk template, from a risk model that has one or more risks defined with parameters. The user can tailor the risk matrix to better match the current borehole design.

The output of step 120 can be a risk matrix for the borehole design concepts for the current borehole design. In some aspects, the risk matrix can be used to update the risk model for use by future borehole designs. Users can adjust one or more factors of each risk assigned, such as adjusting an available equipment weighting factor due to current supply issues.

In a step 130, sub-risk scores can be generated for each risk grouping. In some aspects, the risks are grouped by a design concept. In some aspects, the risks are grouped by a risk level. In some aspects, risks can be grouped by risk levels within each design concept. The risk level can be various types of relative risk categories, for example, high-medium-low, numerical values 1-5, or other types of rankings of at least two or more values.

In a step 140, a final risk score can be generated using the sub-risk scores. The final risk score can be a risk score for the whole borehole design. Step 130 and Step 140 can use one or more statistics-based algorithms, such as a sum, an average, a mean, a median, a weighting system, a ranking systems, or other statistics-based algorithms.

In a decision step 145, a determination can be made on whether there are additional borehole designs to review. If the resultant is “Yes”, method 100 proceeds to step 115. If the resultant is “No”, method 100 proceeds to a step 150.

In a step 150, the available borehole designs can be evaluated using the sub-risk scores and the final risk score. In some aspects, where user review is used, the risk levels can be arranged in order, use color coding, or can use other means to assist the user in evaluating the risk scores. In some aspects, a count of the number of risks within each design concept or within each risk level can be generated and used by the system or the user. In some aspects, the risks or sub-risk scores can be ranked, use weighted parameters, or use a priority indicator to indicate a primary risk or sub-risk. This aspect can allow a machine learning system or a user to evaluate more than one borehole design and select for recommendation a borehole design that best satisfies the risk tolerance parameters.

The system or user can select, e.g., recommend, a borehole design that meets or is better than a risk tolerance parameter. The risk tolerance parameter can be a risk tolerance at a concept grouping, a risk level grouping, or at a final risk score. For example, the risk tolerance parameter can specify that low risks have a risk tolerance of x, medium risks have a risk tolerance of y, and high risks have a risk tolerance of z. If a sub-risk score fails against the risk tolerance parameter, then the borehole design can be disapproved for moving forward. This process can allow the risk tolerance to effectively filter non-satisfactory borehole designs from the review and selection process.

In a step 160, the selected borehole design can be communicated to a process or system, such as a borehole operation planning system. Method 100 ends at a step 195.

FIG. 2 is an illustration of a flow diagram of an example method 200 to update a risk model. Method 200 can be performed, for example, by users performing analysis operations. Method 200 can be performed on a computing system, for example, borehole design analyzer system 300 of FIG. 3 or borehole design analyzer controller 400 of FIG. 4. The computing system can be a reservoir controller, a data center, a cloud environment, a server, a laptop, a mobile device, or other computing system capable of receiving the seismic data, input parameters, and capable of communicating with other computing systems. Method 200 can be encapsulated in software code or in hardware, for example, an application, code library, dynamic link library, module, function, RAM, ROM, and other software and hardware implementations. The software can be stored in a file, database, or other computing system storage mechanism. Method 200 can be partially implemented in software and partially in hardware. Method 200 can perform the steps for the described processes, for example, updating one or more risk matrices of one or more risk models.

A user can update, which includes the ability to create a new risk matrix, one or more risk matrices, such as for various drilling phases, regions, borehole types, or other various design concepts. Method 200 starts at a step 205 and proceeds to a step 210. In step 210, the user selects to create or update a risk matrix of a risk model.

In a step 215, the user selects whether to update an existing risk matrix, create a new matrix, or create a new matrix using an existing matrix. In some aspects, the user can be guided to provide the matrix size, the risk categories to use, and the matrix content. For the matrix size, the user can specify various parameters, for example, a risk matrix name, a risk matrix size, a y-axis, an x-axis, an order of the y-axis, an order of the x-axis, a number of criteria columns, or a number of criteria rows. The risk matrix name is the name of the matrix and allows the user to identify which risk matrix to use in case more than one risk matrix is set up for a risk assessment table. The risk matrix size can provide the number of rows and columns needed for storing the scale number (e.g., quantitative value) used as basis of the risk analysis. The y-axis can be the impact or the probability of the risks. The x-axis can be the alternative of the impact or probability. The order of the y-axis and the order of the x-axis can be the value order used for the respective axis.

In a step 220, the user can specify risk categories. In some aspects, risk categories can be risks associated with specified design concepts. In some aspects, risk categories can be borehole design factors. The risk categories can utilize a risk level range, can specify a color, a qualitative evaluation, such as high-medium-low, a description, and other parameters.

In a step 230, the risk matrix content can be specified, such as specifying parameters or attributes for each risk, as well as ranks, weighting parameters for the risks, or priority indicators. In a step 240, the risk matrix can be used to update one or more risk models. The risk models can be used to evaluate future borehole designs. The risk matrix and risk models can be stored in a database, a machine learning system, a file system, or other type of digital storage system. Proceeding to a step 295, method 200 ends at step 295.

FIG. 3 is an illustration of a block diagram of an example borehole design analyzer system 300, which can be implemented in one or more computing systems, for example, a data center, cloud environment, server, laptop, smartphone, tablet, and other computing systems. In some aspects, borehole design analyzer system 300 can be implemented using a borehole design analyzer controller such as borehole design analyzer controller 400 of FIG. 4. Borehole design analyzer system 300 can implement one or more methods of this disclosure, such as method 100 of FIG. 1 and method 200 of FIG. 2.

Borehole design analyzer system 300, or a portion thereof, can be implemented as an application, a code library, a dynamic link library, a function, a module, other software implementation, or combinations thereof. In some aspects, borehole design analyzer system 300 can be implemented in hardware, such as a ROM, a graphics processing unit, or other hardware implementation. In some aspects, borehole design analyzer system 300 can be implemented partially as a software application and partially as a hardware implementation. Borehole design analyzer system 300 is a functional view of the disclosed processes and an implementation can combine or separate the described functions in one or more software or hardware systems.

Borehole design analyzer system 300 includes a data transceiver 310, a borehole risk analyzer 320, and a result transceiver 330. The generated results, e.g., the risk matrix, the sub-risk scores, the final risk score, recommendations, and interim outputs from borehole risk analyzer 320 can be communicated to a data receiver, such as one or more of a user or user system 360, a computing system 362, or other processing or storage systems 364. The generated results can be used to determine the borehole design to be selected for use by a borehole operation planning system.

Data transceiver 310 can receive input parameters, such as parameters to direct the operation of the analysis implemented by borehole risk analyzer 320. In some aspects, data transceiver 310 can be part of borehole risk analyzer 320.

Result transceiver 330 can communicate one or more generated results, or interim outputs, to one or more data receivers, such as user or user system 360, computing system 362, storage system 364, e.g., a data store or database, or other related systems, whether located proximate result transceiver 330 or distant from result transceiver 330. Data transceiver 310, borehole risk analyzer 320, and result transceiver 330 can be, or can include, conventional interfaces configured for transmitting and receiving data. In some aspects, borehole risk analyzer 320 can be a machine learning system, such as providing a process to update risk matrices and risk models, and providing processes to select and apply risk matrices to borehole designs.

Borehole risk analyzer 320 can implement the analysis and algorithms as described herein utilizing the risk matrices and risk models, the input parameters, and the borehole design concepts. For example, borehole risk analyzer 320 can perform the recommendation process where more than one borehole design is evaluated for risk and the borehole design that best satisfies the risk tolerance parameter is presented as the recommended borehole design. The accepted recommendation can be communicated to another system or process.

In some aspects, borehole risk analyzer 320 can perform the update process to update one or more risk matrices of one or more risk models, where the updated risk models can be utilized by future borehole designs. A memory or data storage of borehole risk analyzer 320 can be configured to store the processes and algorithms for directing the operation of borehole risk analyzer 320. Borehole risk analyzer 320 can also include a processor that is configured to operate according to the analysis operations and algorithms disclosed herein, and an interface to communicate (transmit and receive) data.

FIG. 4 is an illustration of a block diagram of an example of borehole design analyzer controller 400 according to the principles of the disclosure. Borehole design analyzer controller 400 can be a single computer, multiple computers, one or more servers, or one or more cloud environments. The various components of borehole design analyzer controller 400 can communicate via wireless or wired conventional connections. A portion or a whole of borehole design analyzer controller 400 can be located at one or more locations, such as a data center, a cloud environment, a corporate office, a field location, or a combination thereof. In some aspects, borehole design analyzer controller 400 can be part of another system, such as a part of a borehole operation planning system.

Borehole design analyzer controller 400 can be configured to perform the various functions disclosed herein including receiving input parameters, borehole design concepts, and risk models, and generating results from an execution of the methods and processes described herein, such as generating sub-risk scores, final risk score, and recommendations for a borehole design. Borehole design analyzer controller 400 includes a communications interface 410, a memory 420, and a processor 430.

Communications interface 410 is configured to transmit and receive data. For example, communications interface 410 can receive the input parameters, borehole design concepts, and risk models. Communications interface 410 can transmit the generated results, data from the input files, the sub-risk scores, the final risk score, recommendations for the borehole design, or interim outputs. In some aspects, communications interface 410 can transmit a status, such as a success or failure indicator of borehole design analyzer controller 400 regarding receiving the various inputs, transmitting the generated results, or producing the generated results.

In some aspects, communications interface 410 can receive input parameters from a machine learning system, for example, where the borehole design concepts are processed using a risk model and a risk tolerance parameter to generate a recommendation for the borehole design.

In some aspects, the machine learning system can be implemented by processor 430 and perform the operations as described by borehole risk analyzer 320. Communications interface 410 can communicate via communication systems used in the industry. For example, wireless or wired protocols can be used. Communication interface 410 is capable of performing the operations as described for data transceiver 310 and result transceiver 330 of FIG. 3.

Memory 420 can be configured to store a series of operating instructions that direct the operation of processor 430 when initiated, including the code representing the algorithms to determine processing the collected data. Memory 420 is a non-transitory computer readable medium. Multiple types of memory can be used for data storage and memory 420 can be distributed.

Processor 430 can be configured to produce the generated results (e.g., updated risk models, sub-risk scores, final risk score, recommendations for borehole designs, and other results), one or more interim outputs, statuses utilizing the received inputs. For example, processor 430 can apply a risk model to borehole design concepts to generate the sub-risk scores and final risk scores. Processor 430 can be configured to direct the operation of the borehole design analyzer controller 400. Processor 430 includes the logic to communicate with communications interface 410 and memory 420, and perform the functions described herein. Processor 430 is capable of performing or directing the operations as described by borehole risk analyzer 320 of FIG. 3.

FIG. 5 is an illustration of a diagram of an example risk matrix 500. Example risk matrix 500 demonstrates a borehole design concept, labeled “X”, broken down by a risk level and a probability range. Concept X can be one design concept. Borehole design concepts can be determined using other algorithms as well as the demonstrated risk matrix 500. Risk matrix 500 can be used by a process analyzing a borehole design concept, stored in a library, updated in a risk model, or otherwise made available for use by a user or analysis system for a borehole design.

Risk level 510 defines three risk levels of increasing cost going in the up direction. Each risk level has defined the potential costs to the borehole design should the risk become realized. In some aspects, risk matrix 500 can be two or more levels, such as five, ten, or more levels.

Probability chart 515 shows the relative risk scores for each level of the risk as the probability range changes. The probability increases as the chart moves to the right. The risk scores can be of various values, and what is shown is for demonstration purposes. Risk level chart 520 shows how the risks can be grouped into a low-medium-high ranking using the risk scores. In some aspects, other ranking algorithms can be utilized, as well as weighting or other statistics-based algorithms can be used.

FIG. 6 is an illustration of a diagram of an example sub-risk score 600. Sub-risk score 600 demonstrates one scheme for organizing sub-risk scores and a final score for display for a user. Sub-risk score 600 has the sub-risk scores grouped by a risk level 610. Risk level 610 shows three levels, where each risk level has a range of risk scores. Number of risks 615 shows a sum of the number of risks associated with each risk level 610.

Sub-risk score 620 is a sub-risk score of the sub-risks grouped at each of risk levels 610. Sub-risk score 620 utilizes a sum algorithm of the component sub-risks within that risk level. In other aspects, different statistics-based algorithms can be utilized. Total number of risks 630 shows a sum of the number of risks from number of risks 615. Total risk score 635 utilizes a sum algorithm to generate the risk score. In aspects where sub-risk score 600 represents one or more borehole design concepts, total risk score 635 represents the sub-risk score for the borehole design concepts, e.g., a final risk score for the borehole design concept. In aspects where sub-risk score 600 represents the borehole design, total risk score 635 represents a final risk score for the borehole design.

A portion of the above-described apparatus systems or methods may be embodied in or performed by various analog or-digital data processors, wherein the processors are programmed or store executable programs of sequences of software instructions to perform one or more of the steps of the methods. A processor may be, for example, a programmable logic device such as a programmable array logic (PAL), a generic array logic (GAL), a field programmable gate arrays (FPGA), or another type of computer processing device (CPD). The software instructions of such programs may represent algorithms and be encoded in machine-executable form on non-transitory digital data storage media, e.g., magnetic or optical disks, random-access memory (RAM), magnetic hard disks, flash memories, data center storage, cloud environment storage, edge computing storage, and/or read-only memory (ROM), to enable various types of digital data processors or computers to perform one, multiple or all of the steps of one or more of the above-described methods, or functions, systems or apparatuses described herein.

Portions of disclosed examples or embodiments may relate to computer storage products with a non-transitory computer-readable medium that have program code thereon for performing various computer-implemented operations that embody a part of an apparatus, device or carry out the steps of a method set forth herein. Non-transitory used herein refers to all computer-readable media except for transitory, propagating signals. Examples of non-transitory computer-readable media include, but are not limited to: magnetic media such as hard disks, floppy disks, and magnetic tape; optical media such as CD-ROM disks; magneto-optical media such as floppy disks; and hardware devices that are specially configured to store and execute program code, such as ROM and RAM devices, data center servers, cloud environments, or combinations thereof. Examples of program code include both machine code, such as produced by a compiler, and files containing higher level code that may be executed by the computer using an interpreter.

In interpreting the disclosure, all terms should be interpreted in the broadest possible manner consistent with the context. In particular, the terms “comprises” and “comprising” should be interpreted as referring to elements, components, or steps in a non-exclusive manner, indicating that the referenced elements, components, or steps may be present, or utilized, or combined with other elements, components, or steps that are not expressly referenced.

Those skilled in the art to which this application relates will appreciate that other and further additions, deletions, substitutions and modifications may be made to the described embodiments. It is also to be understood that the terminology used herein is for the purpose of describing particular embodiments only, and is not intended to be limiting, since the scope of the present disclosure will be limited only by the claims. Unless defined otherwise, all technical and scientific terms used herein have the same meaning as commonly understood by one of ordinary skill in the art to which this disclosure belongs. Although any methods and materials similar or equivalent to those described herein can also be used in the practice or testing of the present disclosure, a limited number of the exemplary methods and materials are described herein.

Each of the aspects disclosed in the SUMMARY section can have one or more of the following additional elements in combination. Element 1: further including communicating each sub-risk score for each of the one or more borehole design concepts, the final risk score, or the one or more risks for each of the one or more borehole design concepts to a borehole operation planning system. Element 2: further including determining more than one borehole design. Element 3: further including recommending a recommended borehole design from the more than one borehole design, utilizing the sub-risk score for each of the one or more borehole design concepts and the final risk score. Element 4: wherein the recommending utilizes a risk tolerance parameter. Element 5: wherein the recommending is performed by a machine learning system. Element 6: further including grouping the one or more risks from the one or more borehole design concepts utilizing a risk level with at least two levels. Element 7: further including selecting a risk matrix from a risk model, and the assigning the one or more risks utilizes the risk matrix. Element 8: modifying at least one risk from the one or more risks. Element 9: updating a risk matrix. Element 10: wherein the risk matrix is a new risk matrix. Element 11: wherein the modifying at least one risk includes selecting a risk category and at least one risk category attribute. Element 12: wherein the generating the sub-risk score utilizes a rank, weighting parameter, or priority indicator for each risk in each of the one or more borehole design concepts. Element 13: wherein the generating the sub-risk score and the generating the final risk score utilizes a specified algorithm, and the specified algorithm utilizes one of a sum, an average, a mean, or a weighted value. Element 14: wherein the borehole associated data is received from one or more sensors located downhole the borehole. Element 15: further including a machine learning system, capable of communicating with the data transceiver and the borehole risk analyzer, and performing a risk analysis and recommendation process to recommend a recommended borehole design using the borehole location parameters, the borehole associated data, the geographic location of interest, the one or more borehole design concepts, and the one or more risks. Element 16: further including a result transceiver, capable of communicating results, interim outputs, the one or more risks, the sub-risk score for each of the one or more borehole design concepts, and the final risk score to a user system, a data store, or a computing system. Element 17: wherein the computing system is a borehole operation planning system. Element 18: wherein an output from the user system is used to update a risk matrix of a risk model. Element 19: wherein the borehole risk analyzer is further capable of evaluating more than one borehole design. Element 20: further including selecting for recommendation one recommended borehole design from the more than one borehole designs using ranks, weighting parameters, priority indicators, or statistics-based algorithms applied to the one or more risks, the sub-risk score for each of the one or more borehole design concepts, or the final risk score.

What is claimed is:

1. A method to determine one or more risk scores for a borehole design of a borehole, comprising:
receiving borehole location parameters for the borehole, borehole associated data relating to the borehole, and a geographic location of interest for the borehole;
determining one or more borehole design concepts for the borehole utilizing the borehole location parameters, the borehole associated data, and the geographic location of interest, wherein the one or more borehole design concepts are utilized for the borehole design;
assigning one or more risks to each of the one or more borehole design concepts;
generating a sub-risk score for each of the one or more borehole design concepts using the one or more risks; and
generating a final risk score for the borehole design, using the sub-risk score for each of the one or more borehole design concepts.

2. The method as recited in claim 1, further comprising:
communicating each sub-risk score for each of the one or more borehole design concepts, the final risk score, or the one or more risks for each of the one or more borehole design concepts to a borehole operation planning system.

3. The method as recited in claim 1, further comprising:
determining more than one borehole design; and
recommending a recommended borehole design from the more than one borehole design, utilizing the sub-risk score for each of the one or more borehole design concepts and the final risk score.

4. The method as recited in claim 3, wherein the recommending utilizes a risk tolerance parameter.

5. The method as recited in claim 3, wherein the recommending is performed by a machine learning system.

6. The method as recited in claim 1, further comprising:
grouping the one or more risks from the one or more borehole design concepts utilizing a risk level with at least two levels.

7. The method as recited in claim 1, further comprising:
selecting a risk matrix from a risk model, and the assigning the one or more risks utilizes the risk matrix.

8. The method as recited in claim 1, further comprising:
modifying at least one risk from the one or more risks; and
updating a risk matrix.

9. The method as recited in claim 8, wherein the risk matrix is a new risk matrix.

10. The method as recited in claim 8, wherein the modifying at least one risk includes selecting a risk category and at least one risk category attribute.

11. The method as recited in claim 1, wherein the generating the sub-risk score utilizes a rank, weighting parameter, or priority indicator for each risk in each of the one or more borehole design concepts.

12. The method as recited in claim 1, wherein the generating the sub-risk score and the generating the final risk score utilizes a specified algorithm, and the specified algorithm utilizes one of a sum, an average, a mean, or a weighted value.

13. The method as recited in claim 1, wherein the borehole associated data is received from one or more sensors located downhole the borehole.

14. A system to determine one or more risk scores for a borehole design of a borehole, comprising:
a data transceiver, capable of receiving borehole location parameters for the borehole, borehole associated data relating to the borehole, and a geographic location of interest for the borehole; and
a borehole risk analyzer, capable of communicating with the data transceiver, determining one or more borehole design concepts for the borehole utilizing the borehole location parameters, the borehole associated data, and the geographic location of interest, wherein the one or more borehole design concepts are utilized for the borehole design, assigning one or more risks to each of the one or more borehole design concepts, generating a sub-risk score for each of the one or more borehole design concepts, and generating a final risk score for the borehole design, using the sub-risk score for each of the one or more borehole design concepts.

15. The system as recited in claim 14, further comprising:
a machine learning system, capable of communicating with the data transceiver and the borehole risk analyzer, and performing a risk analysis and recommendation process to recommend a recommended borehole design using the borehole location parameters, the borehole associated data, the geographic location of interest, the one or more borehole design concepts, and the one or more risks.

16. The system as recited in claim 14, further comprising:
a result transceiver, capable of communicating results, interim outputs, the one or more risks, the sub-risk score for each of the one or more borehole design concepts, and the final risk score to a user system, a data store, or a computing system.

17. The system as recited in claim 16, wherein the computing system is a borehole operation planning system.

18. The system as recited in claim 16, wherein an output from the user system is used to update a risk matrix of a risk model.

19. The system as recited in claim 14, wherein the borehole risk analyzer is further capable of evaluating more than one borehole design, and selecting for recommendation one recommended borehole design from the more than one borehole designs using ranks, weighting parameters, priority indicators, or statistics-based algorithms applied to the one or more risks, the sub-risk score for each of the one or more borehole design concepts, or the final risk score.

20. A computer program product having a series of operating instructions stored on a non-transitory computer-readable medium that directs a data processing apparatus when executed thereby to perform operations to generate one or more risk scores for a borehole design of a borehole, the operations comprising:
receiving borehole location parameters for the borehole, borehole associated data relating to the borehole, and a geographic location of interest for the borehole;
determining one or more borehole design concepts for the borehole utilizing the borehole location parameters, the borehole associated data, and the geographic location of interest, wherein the one or more borehole design concepts are utilized for the borehole design;
assigning one or more risks to each of the one or more borehole design concepts;
generating a sub-risk score for each of the one or more borehole design concepts using the one or more risks; and
generating a final risk score for the borehole design, using the sub-risk score for each of the one or more borehole design concepts.
